(19) United States
(12) Patent Application Publication
(10) Pub. No.: US 2008/0191310 A1
(43) Pub. Date: Aug. 14, 2008

(54) By-product removal for wafer bonding process

(76) Inventors: Weng-Jin Wu, Hsin-Chu City (TW); Wen-Chih Chiou, Miaoli (TW); Chen-Hua Yu, Hsin-Chu (TW)

Correspondence Address: SLATER & MATSIL, L.L.P., 17950 PRESTON ROAD, SUITE 1000, DALLAS, TX, 75252, US

(21) Appl. No.: 11/705,614

(22) Filed: Feb. 12, 2007

(51) Int. Cl. H01L 29/00; H01L 21/762

(52) U.S. Cl. 257/508; 438/406; 257/E29.001; 257/E21.545

(57) ABSTRACT

A three-dimensional (3D) integrated circuit structure includes a first wafer and a second wafer, each comprising a substrate having devices formed thereon and an interconnect structure over the substrate; a composite layer comprising a first dielectric layer bonded to a second dielectric layer, wherein the composite layer is bonded to the first and the second wafers; a first plurality of openings extending from an interface of the first and the second dielectric layers into the first dielectric layer, wherein each opening of the first plurality of openings is in scribe lines of the first wafer; and vias connecting devices in the first and the second wafers.

### TECHNICAL FIELD

This invention relates generally to integrated circuits, and more particularly to three-dimensional integrated circuits, and even more particularly to a structure and manufacturing processes for forming three-dimensional integrated circuits.

### BACKGROUND

Since the invention of the integrated circuit, the semiconductor industry has experienced continuous rapid growth due to constant improvements in the integration density of various electronic components (i.e., transistors, diodes, resistors, capacitors, etc.). For the most part, this improvement in integration density has come from repeated reductions in minimum feature-size, which allow more components to be integrated into a given area.

These integration improvements are essentially two-dimensional (2D) in nature, in that the volume occupied by the integrated components is essentially on the surface of the semiconductor wafer. Although dramatic improvement in lithography has resulted in considerable improvement in 2D integrated circuit formation, there are physical limits to the density that can be achieved in two dimensions. One of these limits is the minimum size needed to make these components. Also, when more devices are put into one chip, more complex designs are required.

An additional limit comes from the significant increase in the number and length of interconnections between devices as the number of devices increases. When the number and length of interconnections increase, both circuit RC delay and power consumption increase.

Three-dimensional (3D) integrated circuits (ICs) are therefore created to resolve the above-discussed limitations. In a typical 3D integrated circuit formation process, two wafers, each including an integrated circuit, are formed. The wafers are then bonded with the devices aligned. Deep vias are then formed to interconnect devices on the first and second substrates.

Much higher device density has been achieved using 3D IC technology, and up to six layers of wafers have been bonded. As a result, the total wire length is significantly reduced. The number of vias is also reduced. Accordingly, 3D technology has the potential of being the mainstream of the next generation technology.

Direct oxide bonding is one of the commonly used methods for bonding two wafers. In direct oxide bonding, two wafers have oxide layers on the respective surfaces of the wafers and are bonded oxide-to-oxide. Vias are then formed through the oxide layers to electrically connect the wafers.

The conventional direct oxide bonding suffers drawbacks. Typically, in order to improve the bonding quality, Si—H bonds or Si—OH bonds are formed on the surface of the oxides prior to the bonding. During the bonding process and subsequent annealing processes, H₂ or H₂O gas is generated as by-products. The accumulation of H₂ or H₂O gas causes the formation of voids at the bonding interfaces. Various approaches have been developed to solve this problem. In a first approach, wafers are annealed for a relatively long time, so that the H₂ or H₂O gas has adequate time to diffuse out of the wafers. An alternative method is to increase the temperature of the annealing to accelerate the diffusion. Both methods increase the thermal budget, thus are not preferred. In a third approach, an amorphous silicon layer is formed on the surface of the oxide layer, and a plasma treatment is performed to the amorphous silicon, so that dangling bonds are formed. These dangling bonds may form bonds with the released H or OH atoms to avoid the formation of H₂ or H₂O gas. One problem with such a solution is that if a high temperature process is performed subsequently, H₂ or H₂O gas may still be released. As such, the existing technologies are not suitable for 3D integrated circuits, and thus a novel method is needed.

### SUMMARY OF THE INVENTION

In accordance with one aspect of the present invention, a three-dimensional (3D) integrated circuit structure includes a first wafer and a second wafer, each comprising a substrate having devices formed thereon and an interconnect structure over the substrate; a composite layer comprising a first dielectric layer bonded to a second dielectric layer, wherein the composite layer is bonded to the first and the second wafers; a first plurality of openings extending from an interface of the first and the second dielectric layers into the first dielectric layer, wherein the first plurality of openings is in scribe lines of the first wafer; and vias connecting devices in the first and the second wafers.

In accordance with another aspect of the present invention, a 3D integrated circuit structure includes a first semiconductor substrate having devices formed thereon; a first interconnect structure over the first semiconductor substrate; a silicon-containing dielectric layer over the first interconnect structure; a second semiconductor substrate over the silicon-containing dielectric layer, wherein the second semiconductor substrate has devices formed thereon; a second interconnect structure over the silicon-containing dielectric layer; openings in the silicon-containing dielectric layer and in scribe lines of the first and the second semiconductor substrate; and vias connecting the first interconnect structure and the second interconnect structure.

In accordance with yet another aspect of the present invention, a method of forming 3D integrated circuits includes providing a first wafer comprising a first silicon-containing layer on a top surface of the first wafer; forming a first plurality of openings in the first silicon-containing layer and within scribe lines of the first wafer; providing a second wafer comprising a second silicon-containing layer on a top surface of the second wafer; bonding the first and the second wafers by bonding the first and the second silicon-containing layers; and forming vias electrically interconnecting integrated circuits in the first and second wafers.

In accordance with yet another aspect of the present invention, a method of forming 3D integrated circuits includes providing a first wafer comprising a first interconnect structure over a first substrate; forming a first silicon-containing dielectric layer over the first interconnect structure; forming a first plurality of openings in the first silicon-containing dielectric layer and within scribe lines of the first wafer; providing a second wafer comprising a second interconnect structure over a second substrate; a second silicon-containing dielectric layer underlying the second substrate; and a third substrate underlying the silicon-containing dielectric layer. The method further includes attaching a handling wafer over the second interconnect structure; removing the third substrate to expose the second silicon-containing dielectric layer; forming a second plurality of openings in the second silicon-containing dielectric layer; bonding the first and the second wafers by bonding the first and the second silicon-containing dielectric layers; removing the handling wafer; and forming vias connecting the first interconnect structure and the second interconnect structure.

By forming openings at the interfaces between bonded wafers, the by-products generated by the bonding process are released. Fewer voids are formed at the interfaces, and the bonding quality is improved.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 9 illustrate intermediate stages in the manufacture of a three-dimensional integrated circuit; and

FIGS. 10 and 11 illustrate another embodiment of the present invention, wherein two wafers are bonded through two silicon-containing layers.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel method for forming three-dimensional (3D) integrated circuits is provided. The intermediate stages of manufacturing a preferred embodiment of the present invention are illustrated. Throughout the various views and illustrative embodiments of the present invention, like reference numbers are used to designate like elements.

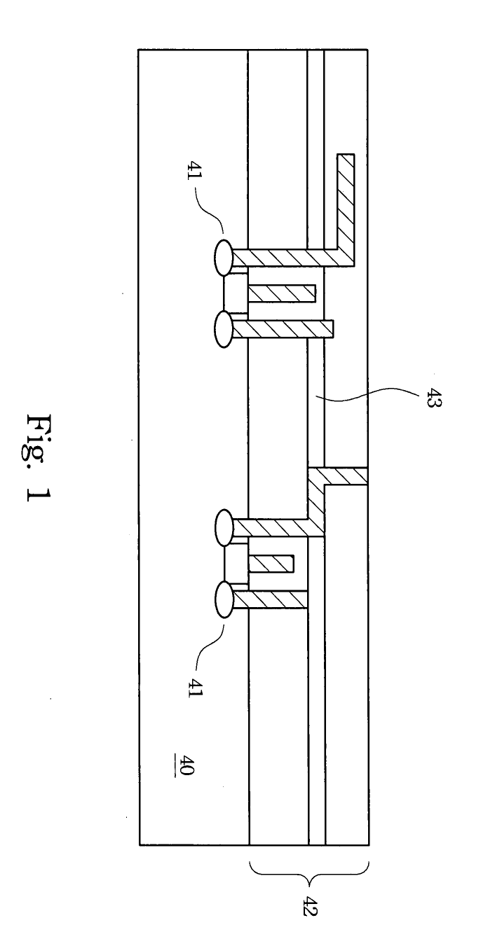

In FIG. 1, a first wafer is provided. In the preferred embodiment, the first wafer has a semiconductor substrate 40 on which devices 41 are formed. As schematically shown, an interconnect structure 42 is formed over semiconductor substrate 40. Interconnect structure 42 includes metallization layers, connecting vias, and dielectric layers in which the metallization layers and connecting vias are formed. An exemplary dielectric layer 43 is shown. For simplicity, dielectric layer 43 is not shown in subsequent drawings. In the preferred embodiment, the dielectric layers include low-k dielectric materials with k values of less than about 3.5. Exemplary low-k dielectric materials include carbon-doped silicon oxide, spin-on organic material, porous materials, and the like.

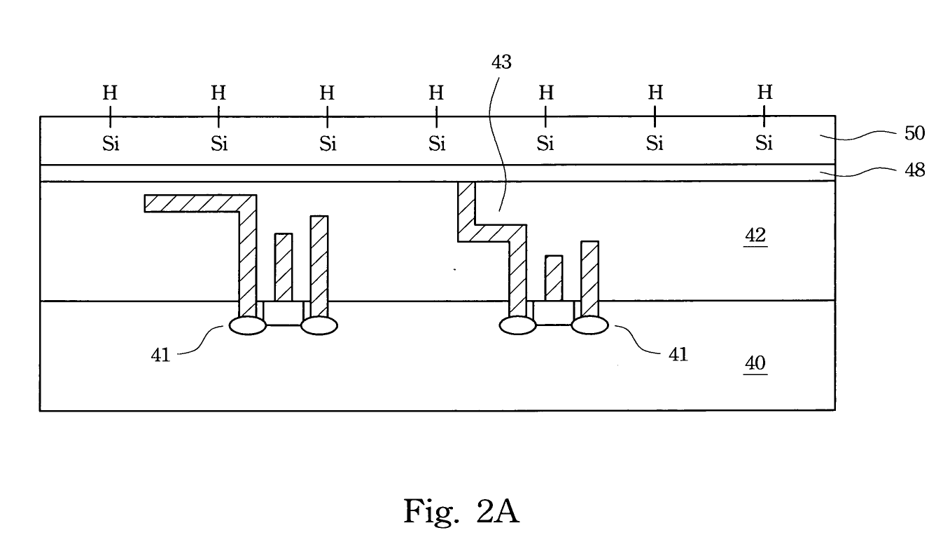

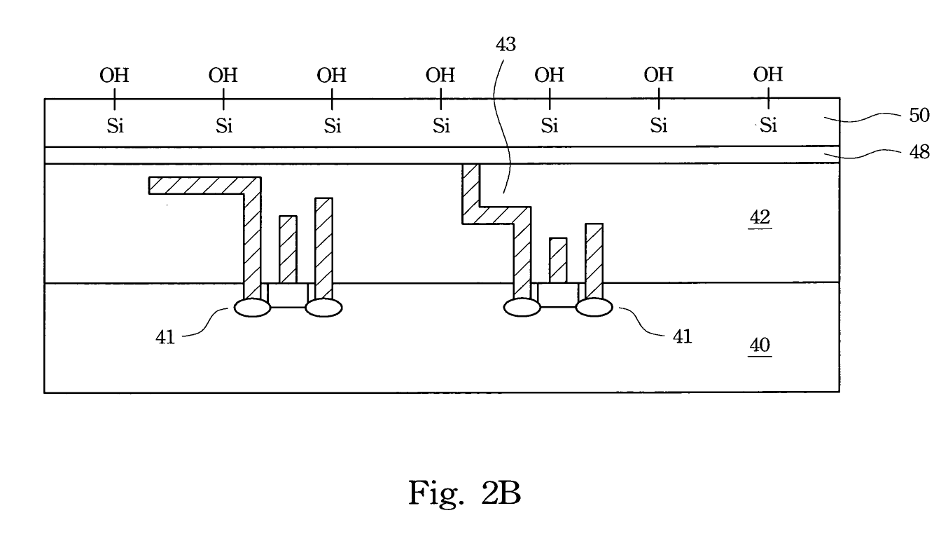

Referring to FIGS. 2A and 2B, after a desired number of metallization layers and corresponding vias are formed, an etch stop layer (ESL) 48 is formed on interconnect structure 42, followed by the formation of a silicon-containing dielectric layer 50. ESL 48 preferably comprises SiC, or other commonly used ESL materials such as SiOC, SiON, SiN can also be used.

Although silicon-containing dielectric layer 50 is preferably an oxide layer containing, for example, silane oxide or tetra-ethyl-ortho-silicate (TEOS) oxide, hence is referred to as oxide layer 50 throughout the description, it can be formed of other silicon-containing dielectric materials, such as SiON, SIOC, and the like. In the preferred embodiment, the formation of oxide layer 50 includes plasma enhanced chemical vapor deposition (PECVD). Alternatively, other low-thermal-budget methods such as carbon-doped silicon oxide and spin-on oxide can also be used. The thickness of oxide layer 50 is preferably between about 1000 Å and about 5000 Å.

Referring to FIG. 2A, a treatment is performed to the surface of oxide layer 50, so that Si—H bonds are generated, wherein the treatment is preferably a wet treatment. In an exemplary wet treatment process, the surface of oxide layer 50 is treated, for example, in a diluted HF solution. Alternatively, a hydrogen plasma treatment is performed, for example, in a hydrogen-containing ambient. Other gases, such as N₂, H₂, NH₃, and combinations thereof, can also be included in the ambient.

FIG. 2B illustrates an alternative embodiment of the present invention, wherein Si—OH bonds are formed on the surface of the oxide layer 50. In a first embodiment, Si—OH bonds are formed by treating the surface of oxide layer 50 in a solution including NH₄OH and water. In a second embodiment, Si—OH bonds are formed by treating the surface of oxide layer 50 in a solution including H₂O₂ and water. In a third embodiment, Si—OH bonds are formed by treating the surface of the oxide layer 50 in a solution including H₂O₂, H₂SO₄ and water. After the wet treatment for forming Si—H or Si—OH bonds, the first wafer is preferably dried and baked.

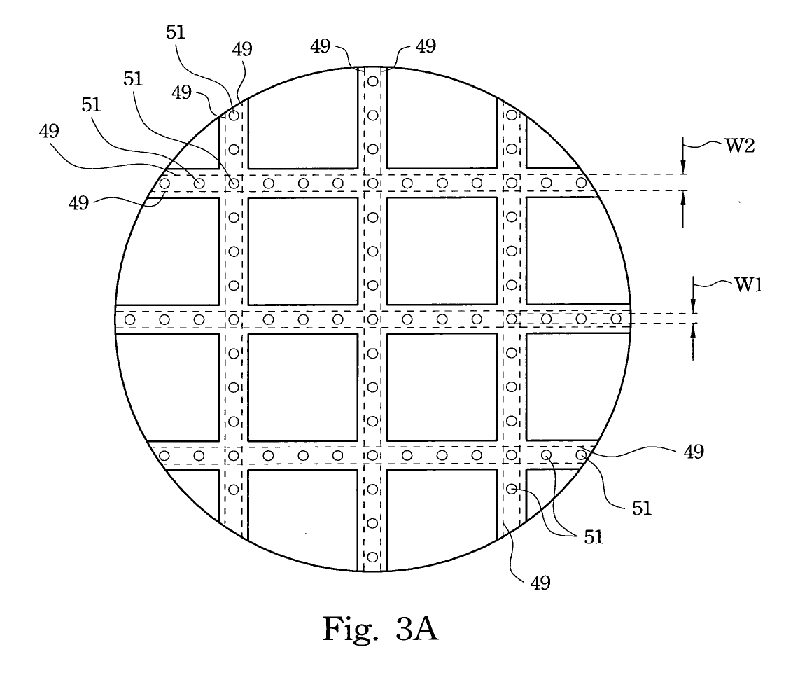

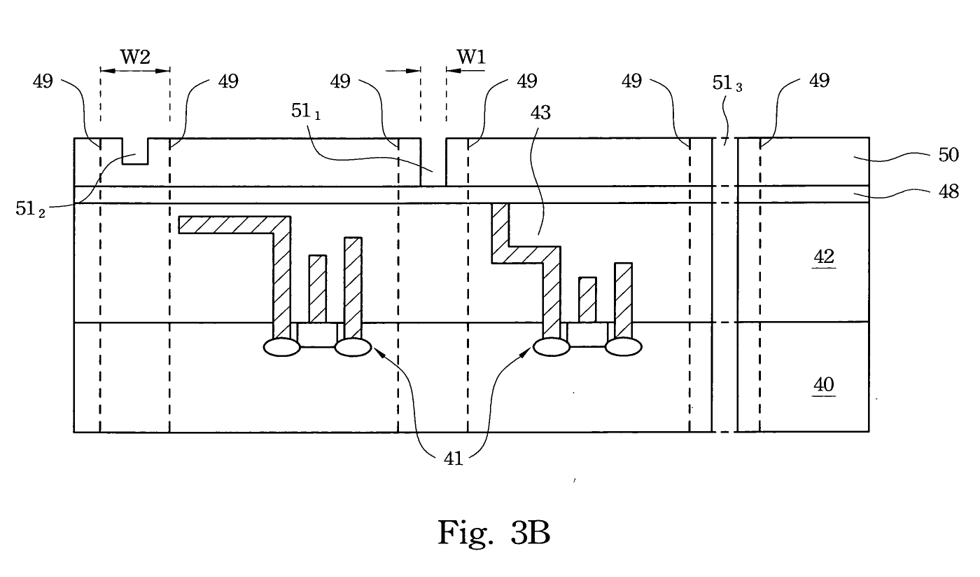

FIGS. 3A and 3B illustrate the formation of openings 51 in the first wafer. FIG. 3A illustrates a top view of the first wafer, which shows openings 51 formed within scribe lines 49. Openings 51 may have any shape, including square, circle, ellipse, star, and the like. Openings 51 may also be arranged in any pattern of any size, such as rows, arrays, and the like, providing they do not exceed the boundaries of scribe lines 49.

A cross-sectional view of a portion of the first wafer is illustrated in FIG. 3B, which shows exemplary openings 51 having different depths. In the preferred embodiment, openings 51 have a depth substantially close to a depth of the oxide layer 50, as illustrated by an exemplary opening 51₁. In other embodiments, openings 51 have a depth less than a depth of the oxide layer 50, as illustrated by an exemplary opening 51₂. In yet other embodiments, openings 51 have a depth substantially greater than a depth of the oxide layer 50. One of the exemplary openings, opening 513, is shown as a through-opening in the wafer. Preferably, all openings 51 on one wafer have a same depth, so that the formation process is simplified, although openings with different depths may be formed on one wafer. The preferred methods for forming openings 51 include laser drilling, plasma etching, and other commonly used methods. In an exemplary plasma etching process, a mask, for example, a photo resist, is formed and patterned on oxide layer 50. A plasma etching is then performed to form openings 51 through openings in the mask.

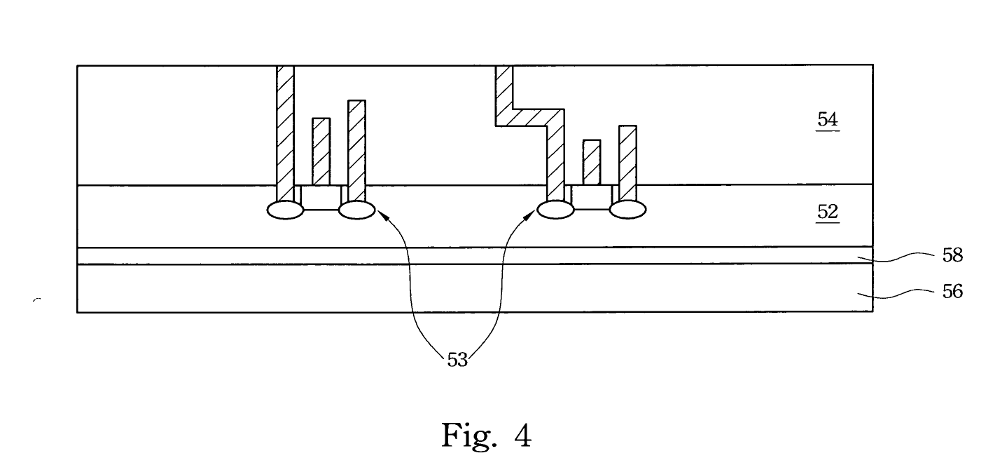

FIG. 4 illustrates a second wafer including a substrate 52, which comprises devices 53 formed thereon. An interconnect structure 54 is then formed over substrate 52. Similar to the first wafer, the interconnect structure 54 includes metallization layers and connecting vias in the dielectric layers. For one embodiment, the substrate in the second wafer has a silicon-on-insulator structure, wherein silicon substrate 52 is located on a silicon-containing dielectric layer 58 (also referred to as an oxide layer 58 throughout the description), which further resides on a semiconductor material 56. Oxide layer 58 may be formed of same or different materials as oxide layer 50 (refer to FIGS. 2A and 2B).

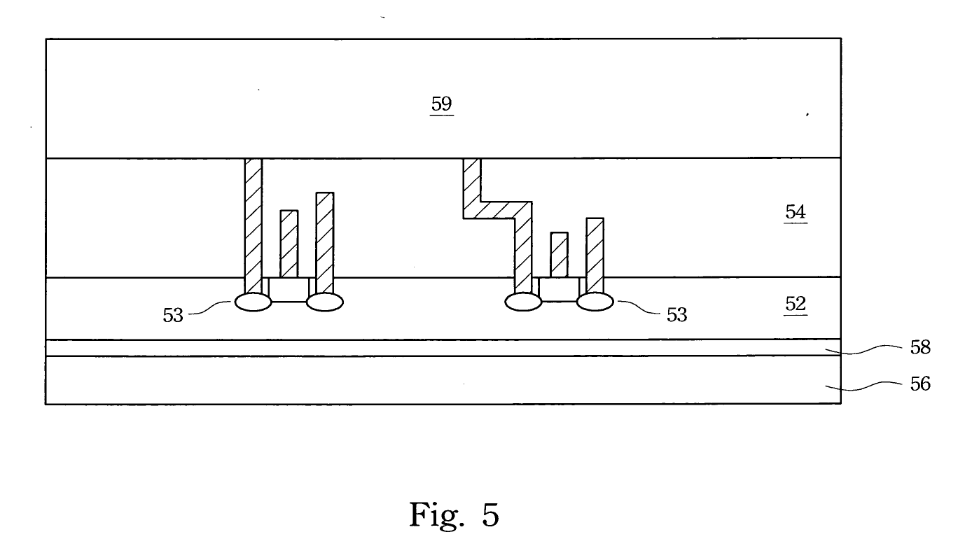

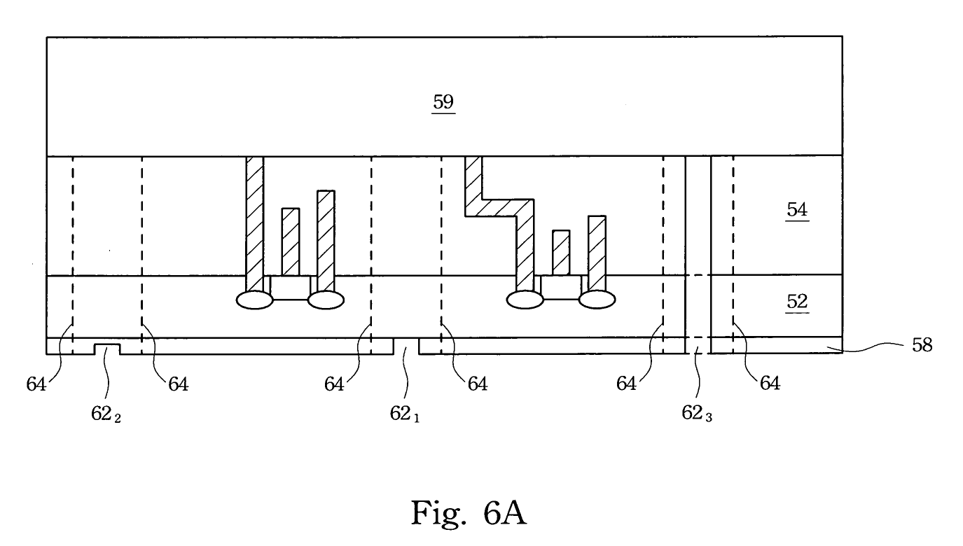

Referring to FIG. 5, a handling wafer 59 is attached over the interconnect structure 54. As is known in the art, handling wafers may comprise glass, silicon oxide, aluminum oxide, and the like. An adhesive (not shown) is used to glue handling wafer 59 to the interconnect structure 54. In an exemplary embodiment, the adhesive is an ultraviolet (UV) glue, which loses its adhesive quality when exposed to UV lights. The second wafer is then thinned by removing semiconductor material 56, thus exposing oxide layer 58. The removal of semiconductor layer 56 may be performed by a chemical mechanical polish (CMP) process. The resulting structure is shown in FIG. 6A.

In the preferred embodiment, the exposed surface of the oxide layer 58 is also treated to form Si—H or Si—OH bonds, using essentially the same methods as used for treating oxide layer 50. Openings 62, which may have different depths, are then formed in oxide layer 58, as illustrated as openings 62₁, 62₂ and 62₃. Again, although openings with different depths may coexist on a same wafer, it is preferable to form openings having the same depth in one wafer. Openings 62 are preferably within the boundary of scribe lines 64. FIG. 6B illustrates a bottom view of the second wafer. The specifications for openings 62 are preferably the same as those for openings 51 (refer to FIGS. 3A and 3B).

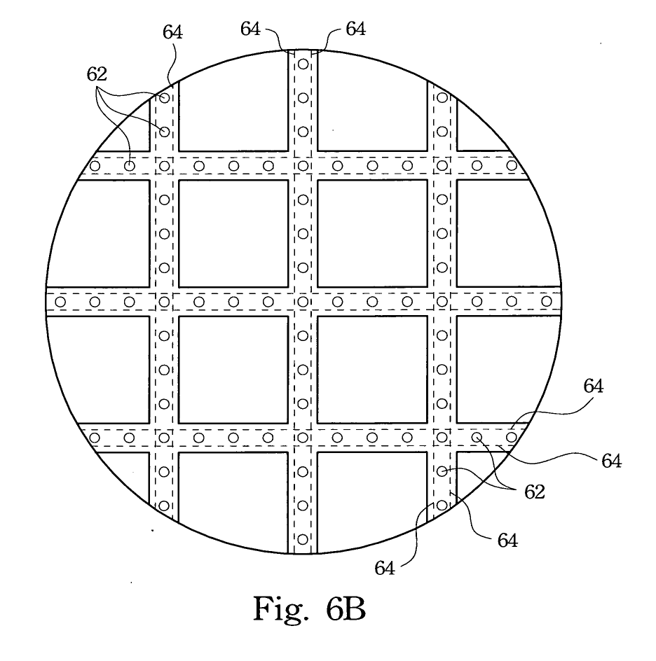

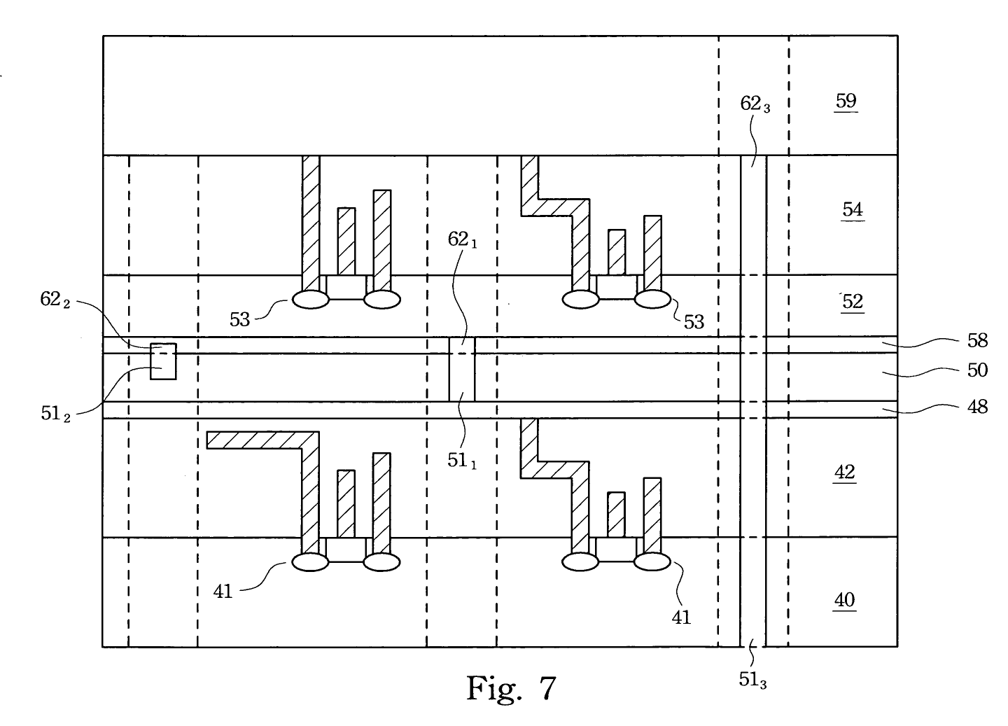

Referring to FIG. 7, the second wafer as shown in FIG. 6A is placed on top of the first wafer as shown in FIG. 3B. The two wafers are then aligned, and a direct oxide bonding is performed. Preferably, the bonding is performed by pressing the first and the second wafers against each other. The bonding may be performed at room temperature or at an elevated temperature. During the bonding process, the silicon or oxygen atoms in silicon oxide layer 50 form covalent bonds with silicon or oxygen atoms in oxide layer 58. The bonded wafers are then annealed. In the preferred embodiment, the anneal temperature is between about 100° C. and about 500° C.

Depending on the bonds on the surfaces of oxide layers 50 and 58, several possible reactions may occur. If the surfaces of oxide layers 50 and 58 have Si—OH bonds, each of the oxide layers 50 and 58 contributes a Si—OH bond. The reaction may be represented as:

Si—OH+Si—OH→Si—O—Si+H₂O. [Eq. 1]

If the surfaces of oxide layers 50 and 58 have Si—H bonds, each of the oxide layers 50 and 58 contributes a Si—H bond. The reaction may be represented as:

Si—H+Si—H→Si—Si+H₂. [Eq. 2]

If one of the surfaces of oxide layers 50 and 58 has Si—H bonds, and the other has Si—OH bonds, the reaction may be represented as:

Si—H+Si—OH→Si—O—Si+H₂. [Eq. 3]

As indicated in the equations, by-products H₂ or H₂O (moisture) are formed. To achieve thermodynamic equilibrium, H₂ or H₂O tends to diffuse into openings 51 and 62, thus openings 51 and 62 have high concentrations of the by-products. Accordingly, the likelihood that H₂ or H₂O molecules are accumulated at the interfaces of oxide layers 52 and 58 (at locations other than openings 51 and 60) to form voids is significantly reduced.

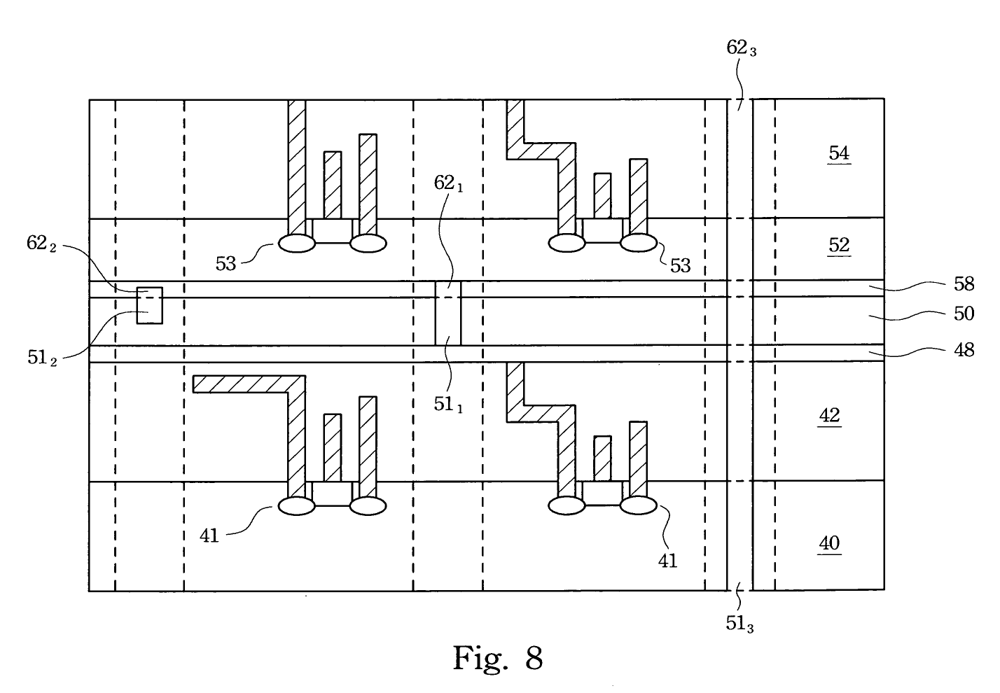

FIG. 8 illustrates the removal of handling wafer 59. In an exemplary embodiment wherein UV glue is used, the UV glue is exposed to UV lights, so that the UV glue loses its adhesive properties, and the handling wafer 59 is easily detached.

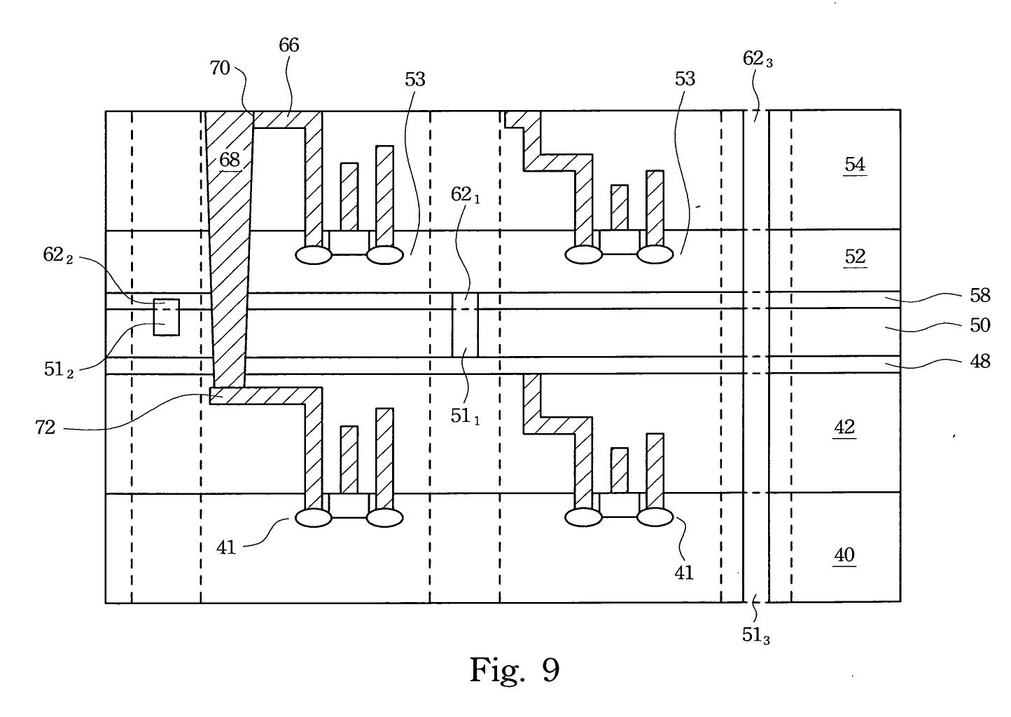

FIG. 9 illustrates the formation of an electrical connection between the first and the second wafer. A metallization layer, which includes a metal line 66, is first formed on top of the previously formed structure. Alternatively, the metallization layer may be pre-formed when the interconnect structure 54 is formed.

FIG. 9 also illustrates the formation of via 68. Preferably, an opening is formed extending from the top surface of the top metallization layer to a metal line 72 in interconnect structure 42. A side edge 70 of the metal line 66 is preferably exposed from within the opening. A metallic material is then filled in the opening, connecting the metal line 66 and the metal line 72. Excess metallic material is then removed by a CMP. The remaining metallic material forms a via 68. The integrated circuits in the first wafer and the second wafer are thus interconnected. If the resulting structure in FIG. 9 is considered as a first wafer, and the processes illustrated in FIGS. 2 through 9 are repeated, more wafers (not shown) can be bonded to the structure in FIG. 9.

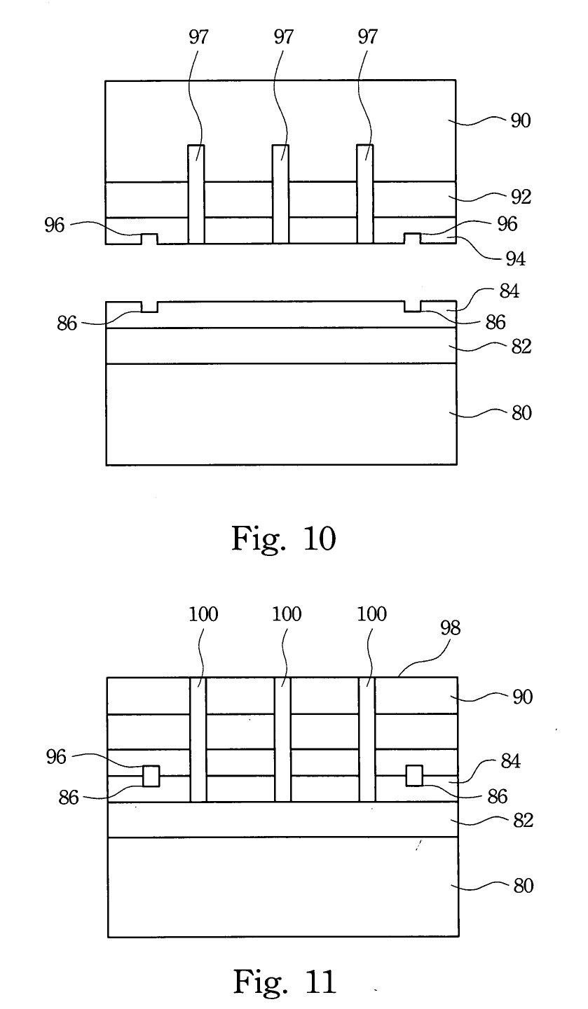

In alternative embodiments of the present invention, the concept of forming openings at the surfaces to be bonded is applicable to the bonding between silicon surfaces. In an embodiment illustrated in FIG. 10, a third wafer is provided, which includes substrate 80 and devices (not shown) formed therein. Substrate 80 is covered with a dielectric layer(s) 82, which further includes metallization layers and connecting vias therein. Silicon-containing layer 84, which includes amorphous silicon, polysilicon and other dielectric materials such as SiOx, is formed on dielectric layer 82, and is surface-treated to have Si—H and/or Si—OH bonds, and the treatment method may be the same as discussed in preceding paragraphs. Openings 86 are formed on silicon-containing layer 84, wherein openings 86 preferably extend into silicon-containing layer 84.

Similar to the third wafer, a fourth wafer includes substrate 90, dielectric layer 92 including metallization layers and connecting vias formed therein, and silicon-containing layer 94 is provided. Substrate may have devices formed therein. Silicon containing layer 94 is also surface-treated to have Si—H and/or Si—OH bonds. Openings 96 are then formed. Substrate 90 may further contain dielectric plugs 97.

Referring to FIG. 11, the fourth wafer is face-to-face bonded to the third wafer. The backside of the fourth wafer is then thinned to expose the back surface 98. Dielectric plugs 97 is also exposed. Through-wafer-vias 100 are thus formed by replacing dielectric plugs 97 with conductive materials. Through-wafer-vias 100 extends from back surface 98 to contact the metallization layers in dielectric layer 82.

In the previously discussed embodiments, openings are formed in both the first and the second wafers. In alternative embodiments, openings can be formed in only one of the first and the second wafers.

The 3D IC structure formed in the previous steps is then sawed along scribe lines to separate individual dies. Each of the openings 51 and 62 are preferably at least partially within a kerf line, so that accumulated H₂ or H₂O gas is released.

The previously discussed embodiment is commonly referred to as back-to-front bonding since a back side of the second wafer is bonded to a front side of the first wafer. One skilled in the art will realize that with the teaching in the preferred embodiments, back-to-back bonding and front-to-front bonding can also be performed. These embodiments preferably include providing or forming a silicon-containing dielectric layer on a desired side of one wafer, and providing or forming a silicon-containing dielectric layer on a desired side of another wafer. Openings are drilled in each of the silicon-containing dielectric layers. Two wafers are then bonded by forming covalent bonds. One skilled in the art will realize the respective process steps.

By forming openings in silicon-containing dielectric layers, the accumulation of by-product gases, such as H₂ or H₂O, at the interfaces of the bonded oxide layers is reduced. As a result, voids at the interface are reduced and the bonding quality is improved.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A three-dimensional (3D) integrated circuit structure comprising:
a first wafer and a second wafer, each comprising a substrate having devices formed thereon and an interconnect structure over the substrate;
a composite layer comprising a first dielectric layer bonded to a second dielectric layer, wherein the composite layer is bonded to the first and the second wafers;
a first plurality of openings extending from an interface of the first and the second dielectric layers into the first dielectric layer, wherein the first plurality of openings is in scribe lines of the first wafer; and
vias connecting devices in the first and the second wafers.

2. The 3D integrated circuit structure of claim 1, wherein the second wafer further comprises a second plurality of openings extending from an interface of the first and the second dielectric layers into the second dielectric layer, wherein the second plurality of openings is in scribe lines of the second wafer.

3. The 3D integrated circuit structure of claim 1, wherein the first and the second dielectric layers are silicon-containing dielectric layers.

4. The 3D integrated circuit structure of claim 3, wherein the first and the second dielectric layers are silicon-containing oxide layers.

5. The 3D integrated circuit structure of claim 1, wherein each opening in the first plurality of openings has a depth less than a thickness of the first dielectric layer.

6. The 3D integrated circuit structure of claim 1, wherein each opening in the first plurality of openings has a depth equal to a thickness of the first dielectric layer.

7. The 3D integrated circuit structure of claim 1, wherein each opening in the first plurality of openings has a depth greater than a thickness of the first dielectric layer.

8. The 3D integrated circuit structure of claim 7, wherein each opening in the first plurality of openings is a through-opening in the first wafer.

9. The 3D integrated circuit structure of claim 1, wherein the interface between the first and the second dielectric layers comprises a bond selected from the group consisting essentially of Si—Si bond and Si—O—Si bond.

10. The 3D integrated circuit structure of claim 1 further comprising a third wafer bonded to the second wafer, wherein a dielectric layer of the third wafer is bonded to a dielectric layer of the second wafer, and wherein the dielectric layer of the third wafer comprises a plurality of openings.

11. A three-dimensional (3D) integrated circuit structure comprising:
a first semiconductor substrate having devices formed thereon;
a first interconnect structure over the first semiconductor substrate;
a silicon-containing dielectric layer over the first interconnect structure;
a second semiconductor substrate over the silicon-containing dielectric layer, wherein the second semiconductor substrate has devices formed thereon;
a second interconnect structure over the silicon-containing dielectric layer;
openings in the silicon-containing dielectric layer and in scribe lines of the first and the second semiconductor substrate; and
vias connecting the first interconnect structure and the second interconnect structure.

12. The 3D integrated circuit structure of claim 11, wherein the silicon-containing dielectric layer comprises a first layer and a second layer bonded by covalent bonds, and wherein the first layer and the second layer are formed of different materials.

13. The 3D integrated circuit structure of claim 11, wherein the openings are limited to the silicon-containing dielectric layer.

14. The 3D integrated circuit structure of claim 11, wherein the openings extend into at least one of the first and the second semiconductor substrates.

15. The 3D integrated circuit structure of claim 11, wherein the openings extend into at least one of the first and the second interconnect structures.

16. The 3D integrated circuit structure of claim 11, wherein the openings comprise at least one through-opening.

17. A method of forming three-dimensional (3D) integrated circuits, the method comprising:
providing a first wafer comprising a first silicon-containing layer on a top surface of the first wafer;
forming a first plurality of openings in the first silicon-containing layer and within scribe lines of the first wafer;
providing a second wafer comprising a second silicon-containing layer on a top surface of the second wafer;
bonding the first and the second wafers by bonding the first and the second silicon-containing layers; and
forming vias electrically interconnecting integrated circuits in the first and second wafers.

18. The method of claim 17 further comprising forming a second plurality of openings in the second silicon-containing layer and within scribe lines of the second wafer.

19. The method of claim 17 further comprising sawing the first and the second wafers into individual chips, wherein each opening of the first plurality of openings is at least partially in kerf lines.

20. The method of claim 17 further comprising performing treatments to the first and the second silicon-containing dielectric layers before the step of bonding.

21. The method of claim 17, wherein the step of forming the first plurality of openings comprises plasma etching or laser drilling.

22. The method of claim 17, wherein each opening of the first plurality of openings is shallower than the first silicon-containing dielectric layer.

23. The method of claim 17, wherein each opening of the first plurality of openings has a depth substantially equal to a depth of the first silicon-containing dielectric layer.

24. The method of claim 17, wherein each opening of the first plurality of openings is a through-opening in the first wafer.

25. The method of claim 17 further comprising;
providing a third wafer comprising a third silicon-containing dielectric layer on a top surface of the third wafer;
forming a third plurality of openings in the third silicon-containing dielectric layer within scribe lines of the third wafer;
bonding the second and the third wafers by bonding the second and the third silicon-containing dielectric layers; and
forming vias electrically interconnecting integrated circuits in the third wafer to the first and second wafers.

26. A method of forming three-dimensional (3D) integrated circuits, the method comprising:
providing a first wafer comprising a first interconnect structure over a first substrate;
forming a first silicon-containing dielectric layer over the first interconnect structure;
forming a first plurality of openings in the first silicon-containing dielectric layer and within scribe lines of the first wafer;
providing a second wafer comprising:
a second interconnect structure over a second substrate;
a second silicon-containing dielectric layer underlying the second substrate; and
a third substrate underlying the silicon-containing dielectric layer;
attaching a handling wafer over the second interconnect structure;
removing the third substrate to expose the second silicon-containing dielectric layer;
forming a second plurality of openings in the second silicon-containing dielectric layer;
bonding the first and the second wafers by bonding the first and the second silicon-containing dielectric layers;
removing the handling wafer; and
forming vias connecting the first interconnect structure and the second interconnect structure.

27. The method of claim 26 further comprising treating the first and the second silicon-containing dielectric layers to form Si—H bonds or Si—OH bonds before the step of bonding the first and the second silicon-containing dielectric layers.

28. The method of claim 26 further comprising sawing the first and the second wafers into dies, wherein each opening of the first and the second plurality of openings is at least partially within a kerf line.
